(19) United States
(12) Patent Application Publication
(10) Pub. No.: US 2011/0215805 A1
(43) Pub. Date: Sep. 8, 2011

(54) MRI and method using multi-slice imaging

(75) Inventor: Mark Doyle, Wexford, PA (US)

(73) Assignee: Allegheny-Singer Research Institute

(21) Appl. No.: 12/660,724

(22) Filed: Mar. 3, 2010

(51) Int. Cl. G01R 33/48

(52) U.S. Cl. 324/309

(57) ABSTRACT

An MRI for a patient includes an imaging coil for sparsely sampling multiple slices of k-space data across a spatial dimension and a temporal dimension to produce associated signals. The MRI includes a receiving coil which receives the associated signals of the multiple slices. The MRI includes a memory in which the associated signals of the multiple slices are stored. The MRI includes a processing unit which processes the associated signals of the multiple slices altogether at essentially a same time to produce an image of the patient. A method of using an MRI for a patient. A method of using an MRI for a patient's heart.

### FIELD OF THE INVENTION

The present invention is related to an MRI that sparsely samples multiple slices of k-space data across a spatial dimension and a temporal dimension to produce associated signals. (As used herein, references to the “present invention” or “invention” relate to exemplary embodiments and not necessarily to every embodiment encompassed by the appended claims.) More specifically, the present invention is related to an MRI that sparsely samples multiple slices of k-space data across a spatial dimension and a temporal dimension to produce associated signals where the associated signals of the multiple slices are processed altogether at essentially a same time to produce an image of the patient.

### BACKGROUND OF THE INVENTION

This section is intended to introduce the reader to various aspects of the art that may be related to various aspects of the present invention. The following discussion is intended to provide information to facilitate a better understanding of the present invention. Accordingly, it should be understood that statements in the following discussion are to be read in this light, and not as admissions of prior art.

There are a number of approaches that use sparse sampling to acquire time resolved data in a rapid manner. However, these approaches are suitable for either a single slice or a volume of data that is resolved over time. When applied to volume data, the entire volume is excited and data acquired simultaneously from the whole volume. Typically, a 3D Fourier (or similar) encoding technique is applied to resolve the volume data into a series of slices after completion of the acquisition and appropriate processing steps. It is noted that 3D approaches have several advantages over successive multiple slice 2D approaches, including increased signal to noise ratio and ability to encode thinner slices. Further, when considering sparse sampling schemes, the sparse sampling schemes can generally be efficiently applied to encode 3D data. However, it is not always possible, or desirable, to acquire data in a direct 3D manner. For instance, in situations where motion may disrupt the image it may be better to acquire data as a series of 2D slices directly. Further, when acquiring data in a breath-hold mode, even an accelerated 3D scan may take too long for a comfortable breath hold, and this is often the case in cardiovascular imaging where it is common to acquire multiple 2D slices of data in a time resolved manner, each slice or a number of slices are acquired in a breath hold time, with several separate breath holds required to acquire the full set of slices. As noted above, sparse sampling schemes can be applied to each of the 2D time resolved acquisitions separately. Here an approach is described, Slice Interlaced Capture of k-space (SLICK), that allows the temporal continuity across slices to be exploited to acquire data 30-40% faster than a comparable multiple 2D series of slices in which each slice is considered in isolation.

### BRIEF SUMMARY OF THE INVENTION

The present invention pertains to an MRI for a patient. The MRI comprises an imaging coil for sparsely sampling multiple slices of k-space data across a spatial dimension and a temporal dimension to produce associated signals. The MRI comprises a receiving coil which receives the associated signals of the multiple slices. The MRI comprises a memory in which the associated signals of the multiple slices are stored. The MRI comprises a processing unit which processes the associated signals of the multiple slices altogether at essentially a same time to produce an image of the patient.

The present invention pertains to a method of using an MRI for a patient. The method comprises the steps of sparsely sampling multiple slices of k-space data across a spatial dimension and a temporal dimension with an imaging coil to produce associated signals. There is the step of receiving with a receiving coil the associated signals of the multiple slices. There is the step of storing the associated signals of the multiple slices in a memory. There is the step of processing with a processing unit the associated signals of the multiple slices altogether at essentially a same time to produce an image of the patient.

The present invention pertains to a method of using an MRI for a patient's heart. The method comprises the steps of sparsely sampling multiple slices of k-space data of the heart across a spatial dimension and a temporal dimension with an imaging coil to produce associated signals. There is the step of receiving with a receiving coil the associated signals of the multiple slices. There is the step of storing the associated signals of the multiple slices in a memory. There is the step of processing with a processing unit the associated signals of the multiple slices altogether at essentially a same time to produce an image of the patient.

### BRIEF DESCRIPTION OF THE SEVERAL VIEWS OF THE DRAWING

In the accompanying drawings, the preferred embodiment of the invention and preferred methods of practicing the invention are illustrated in which:

FIG. 1 is an illustration to indicate that the k-space patterns may be dramatically different from one slice to another.

FIG. 2 is an illustration of how slices are spatially and temporally related to each other.

FIG. 3 shows the distribution of k-space lines over the slice direction is illustrated.

FIG. 4 is an illustration of the main steps involved in the SLICK acquisition and data processing.

FIG. 5 is a comparison of SLICK combined with MACH acceleration vs. MACH acceleration applied alone.

FIG. 6 is a block diagram of the present invention.

FIG. 7 is a graph of an example of a sparse sampling factor for MACH.

FIG. 8 is a schematic representation of the k-space-temporal sampling pattern of the sparse sampling scheme of MACH.

FIG. 9 shows the interpolation scheme regarding MACH.

FIG. 10 is a block diagram of implementation of MACH.

FIG. 11 is a schematic of the k-space-temporal sampling patterns of the BRISK sparse sampling scheme.

FIGS. 12a-12d show corresponding frames which illustrate the relative performance of BRISK and MACH with respect to Gibbs ringing artifact.

FIG. 13 shows corresponding frames from three series: original (top), simulated BRISK (middle), and simulated MACH (lower) images.

FIG. 14 shows simulated MACH images obtained with an acceleration factor of 12, corresponding to acquisition of 22 lines of k-space. Frames correspond to those of FIG. 13.

FIG. 15 is a block diagram of MACH.

### DETAILED DESCRIPTION OF THE INVENTION

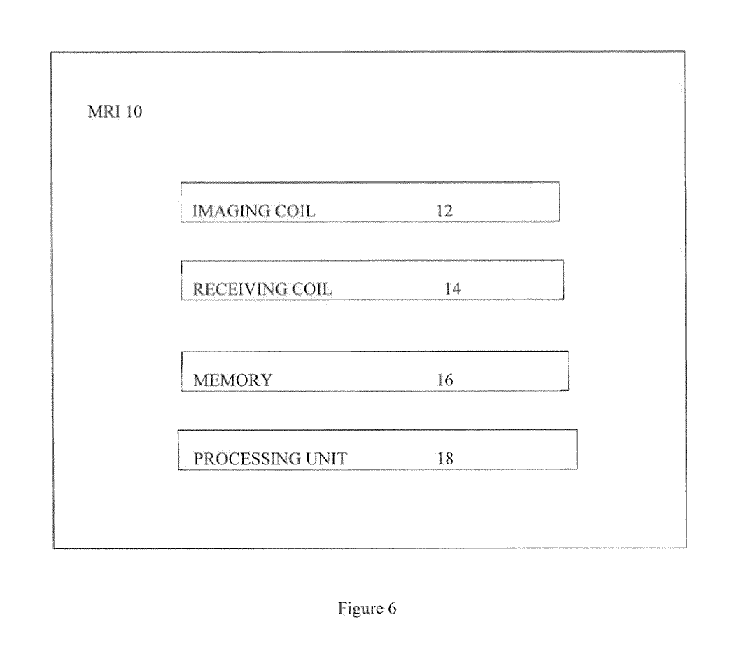

Referring now to the drawings wherein like reference numerals refer to similar or identical parts throughout the several views, and more specifically to FIG. 6 thereof, there is shown an MRI 10 for a patient. The MRI 10 comprises an imaging coil 12 for sparsely sampling multiple slices of k-space data across a spatial dimension and a temporal dimension to produce associated signals. The MRI 10 comprises a receiving coil 14 which receives the associated signals of the multiple slices. The MRI 10 comprises a memory 16 in which the associated signals of the multiple slices are stored. The MRI 10 comprises a processing unit 18 which processes the associated signals of the multiple slices altogether at essentially a same time to produce an image of the patient.

The image coil may sample multiple slices over the spatial dimension, with each slice temporally synchronized. The image coil may apply a sparse sampling pattern along a slice direction. The processing unit 18 may condition the signals along the slice direction. The processing unit 18 may perform signal estimation of missing data by interpolation between corresponding points along the slice direction. The processing unit 18 may use time data for each slice to interpolate along a time direction thereby filling in all time points either with the data or with a temporally interpolated value.

The processing unit 18 may condition the k-space data by subtracting an estimate of the k-space data from the sampled data. The processing unit 18 may interpolate between the conditioned k-space data with respect to the slice direction to estimate each missing k-space data. The processing unit 18 may add in the k-space data estimates to the spatially interpolated data to produce full k-space data sets for each timeframe for each slice. The processing unit 18 may perform a second interpolation along the time direction of original sampled data and spatially interpolated data.

The present invention pertains to a method of using an MRI 10 for a patient. The method comprises the steps of sparsely sampling multiple slices of k-space data across a spatial dimension and a temporal dimension with imaging coils 12 to produce associated signals. There is the step of receiving with a receiving coil 14 the associated signals of the multiple slices. There is the step of storing the associated signals of the multiple slices in a memory 16. There is the step of processing with a processing unit 18 the associated signals of the multiple slices altogether at essentially a same time to produce an image of the patient.

The sampling step may include the step of sampling multiple slices over the spatial dimension, with each slice temporally synchronized. There may be the step of applying a sparse sampling pattern along a slice direction. There may be the step of conditioning the signals along the slice direction. There may be the step of performing signal estimation of missing data by interpolation between corresponding points along the slice direction. The conditioning step may include the step of using time data for each slice to interpolate along a time direction thereby filling in all time points either with the data or with a temporally interpolated value.

There may be the step of conditioning the k-space data by subtracting an estimate of the k-space data from the sampled data. There may be the step of interpolating between the conditioned k-space data with respect to the slice direction to estimate each missing k-space data. There may be the step of adding in the k-space data estimates to the spatially interpolated data to produce full k-space data sets for each timeframe for each slice. There may be the step of performing a second interpolation along the time direction of original sampled data and spatially interpolated data.

The present invention pertains to a method of using an. MRI 10 for a patient's heart. The method comprises the steps of sparsely sampling multiple slices of k-space data of the heart across a spatial dimension and a temporal dimension with imaging coils 12 to produce associated signals. There is the step of receiving with a receiving coil 14 the associated signals of the multiple slices. There is the step of storing the associated signals of the multiple slices in a memory 16. There is the step of processing with a processing unit 18 the associated signals of the multiple slices altogether at essentially a same time to produce an image of the patient.

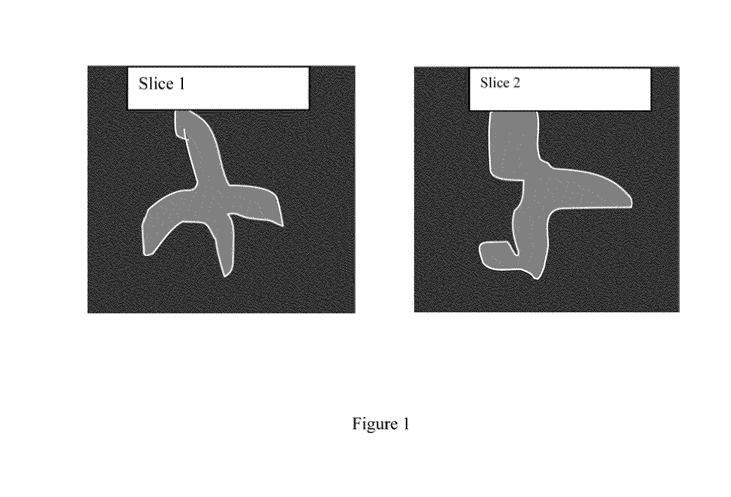

In the operation of the invention, there are several difficulties associated with applying sparse sampling schemes across multiple slices, including 1) the k-space configuration for each slice typically does not exhibit a smooth change in form between slices, leading to low correlation between k-space patterns over successive slices (FIG. 1), 2) each slice or group of slices may have to be acquired in separate breath hold periods, leading to the possibility of further misregistration between slices due to differences in the breath hold position, and 3) depending on the physical distance between slices, new image features may be present in some slices that are not present in adjacent slices, leading to sudden discontinuities of k-space features between slices. Despite these characteristics, in slices that are acquired in a similar time resolved manner (e.g. triggered to the cardiac cycle, or during passage of a contrast agent) correlations will exist between k-space data, but related to the manner in which each region of k-space varies with time. That is, while the k-space patterns of each slice exhibit dramatic differences in pattern (FIG. 1), changes in k-space patterns over time tend to be related between slices. FIG. 1 is an illustration to indicate that the k-space patterns may be dramatically different from one slice to another. In SLICK, the aspect of the temporal relationship between slices is isolated from the general form of k-space, allowing the signal correlation to contribute to reducing the scan time by application of sparse sampling along the slice direction.

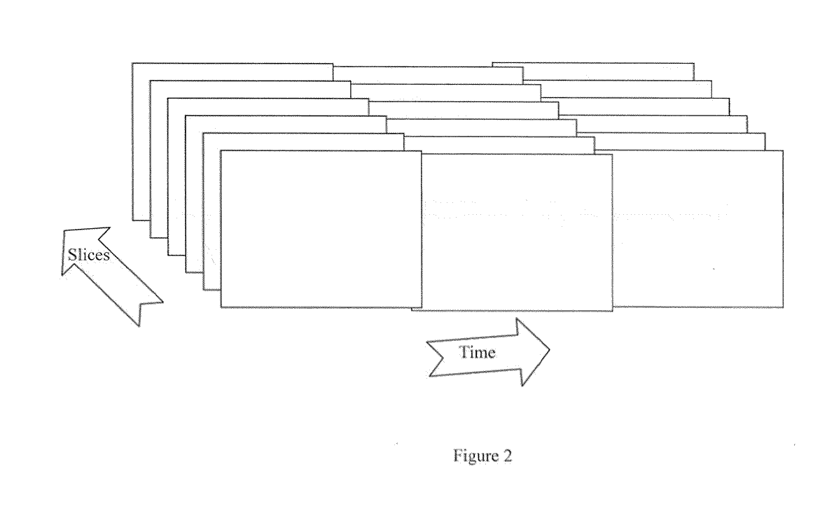

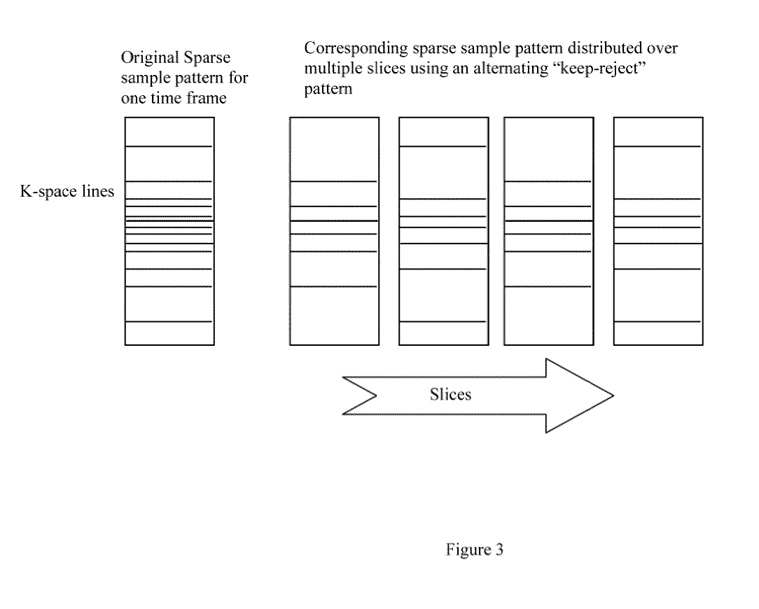

The SLICK approach can be used in conjunction with prior art temporal sparse sampling schemes such as MACH, which are applied to 2D and 3D timer resolved data. However, it is not essential that such schemes be applied with SLICK. For the purpose of illustration, SLICK was simulated in conjunction with MACH imaging. Consider a time series of multiple slices, FIG. 2. FIG. 2 is an illustration of how slices are spatially and temporally related to each other. At each temporal position, k-space data from each of the slices are acquired, also for each slice, k-space data are acquired over the cardiac cycle. The sparse sampling strategy for SLICK, if used in conjunction with an approach such as MACH applied along the temporal direction can be applied in a variety of manners. Here an example algorithm is given: 1) decide on the MACH sparse sampling scheme and generate the sparse sampling pattern for a representative slice. For example, a sampling scheme may be used whereby only 25% of the full scan data are acquired at any given time frame of the series. In the MACH sampling scheme, the sampling density is higher towards the center of k-space. However, the sampling density along the slice direction does not generally conform to this condition. 2) Apply a sparse sampling pattern along the slice direction, in this example, for each position of k-space acquired by the original MACH scheme, apply a uniform spars factor of 2 along the slice direction. This is most efficiently done such that in this example, 50% of k-space data are to be acquired in each slice at each time point. One algorithm to achieve this would be to alternately apply the “keep-reject” pattern for k-space data, FIG. 3. FIG. 3 shows the distribution of k-space lines over the slice direction is illustrated. The left panel shows the sparse k-space pattern for one time frame, as it would be applied to a single slice acquisition. The left panel shows how that basic pattern of sparse sampling is distributed along the slice direction, in this case using an alternating pattern of “keep or reject” applied to each sample point. In this example, the sampling density for any one time frame of any one slice (right panel) is halved compared to the single slice considered alone (left panel).

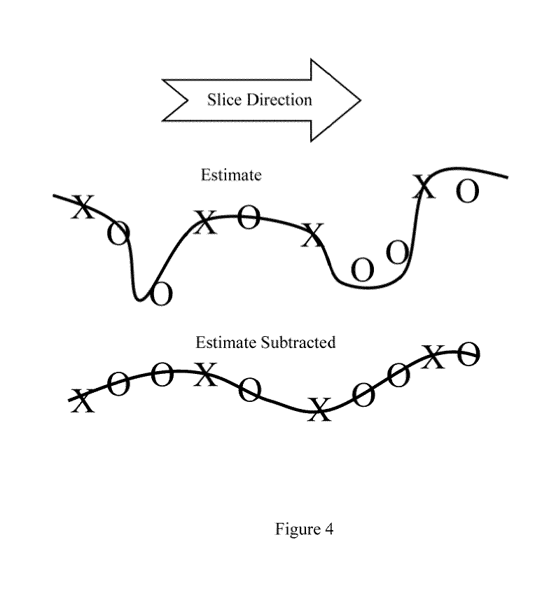

Due to the dramatic discontinuities that exist between k-space patterns across the slice direction the missing data distributed over the slice direction cannot, in general, be generated with acceptable fidelity by interpolation. A key step of SLICK is to condition the signal along the slice direction prior to performing signal estimation of missing data by interpolation between corresponding points along the slice direction. In SLICK, an example of the step of signal conditioning is performed as follows: 1) using the time data for each slice, interpolate along the time direction, thereby filling in all time points, either with original data or with a temporally interpolated value (FIG. 4). FIG. 4 is an illustration of the main steps involved in the SLICK acquisition and data processing. The top panel shows the estimated variation in k-space intensity for a common point in k-space resolved over the slice direction. The sampled points (X) and missing points (O) resolved over the slice direction are shown. The lower panel shows the sampled and missing points for the original k-space points with the estimate values subtracted. Since the estimate subtracted function has a variation of lower complexity compared with the original function, the process of estimating the missing points (circles) from the knowledge of the sampled points (crosses) can be conducted with lower errors when using approaches such as data interpolation. Since the time data may not be distributed in a manner suitable for accurate interpolation, these data are generally of poor quality. 2) Condition the k-space data by subtracting the estimate of the k-space data from the sampled data. 3) With respect to the slice direction, interpolate between the conditioned k-space data to estimate each missing k-space data. 4) Add in the k-space estimates to the original and spatially interpolated data to produce full k-space data sets for each time frame for each slice. 5) In the case of data that were also sparsely sampled along the time direction, even after filling in the data that were sparsely distributed along the slice direction, the data remain sparsely distributed along the time direction for each slice. However, at this stage, the data that were distributed along the slice direction (e.g. every other point missing) are now filled in with a superior estimate compared to the estimate obtained in stage 1 (of interpolation only along the time dimension). The process is made iterative by performing a second interpolation along the time direction of original sampled data and spatially interpolated data. This second estimate of k-space is used to condition the k-space data as in step 2 above (by subtracting). The steps of interpolating along the slice direction (3 above) and adding back in the estimated k-space data (step 4 above) are repeated. After one iteration, the estimate of k-space is sufficient for most imaging purposes. However, further iterations of the processing approach are possible.

Signal Conditioning Approach

The step of conditioning the signal in the SLICK acquisition prior to interpolating over the spatial dimension is central to the success of SLICK. Without conditioning, applying interpolation to the original k-space data along the slice direction typically results in dramatic Gibbs ringing artifacts, and in extreme cases, the appearance of aliased signals in the image generated from this interpolated data. A means of conditioning the signal is described here, whereby each k-space data set is formulated using the following equation:

KD_{St}=MF_{St}×IE_{S}

where ‘KD’ is the k-space data, ‘MF’ is the modulating function, and ‘IE’ is the initial estimate of the k-space data, the suffix ‘S’ denotes a particular slice, and ‘t’ denoted a particular time point. Thus, it is apparent form the formula that there is one modulating function (MF) per slice at each time point, while there is only one initial estimate (IE) per slice. For example, if there were 8 slices and 20 time points, there would be 160 modulating functions, and 8 initial estimates. It is noted that for a series of closely related slices, each acquired in a synchronized time resolved manner, there is generally a strong relationship in the manner in which the slice information changes over the time series, which is represented in the modulating function above. However, since each slice encompasses new features in the imaged object, the form of the k-space data may be dramatically different between slices, which is represented in the initial estimate above. To condition the data set of multiple slices into a format suitable for SLICK processing an initial estimate of the k-space data for each slice is generated. This initial estimate is generated by interpolating the sparsely sampled k-space data along the time axis and averaging each frame over the time extent of the k-space data, i.e. one average k-space data set is generated for each slice. To generate the series of modulating functions (above), the original k-space for each time point of a slice is divided by the initial estimate for that slice. To avoid dividing by zero, all zero data in the initial estimates can be replaced by a small number (e.g. 0.00000001). Since the original k-space data are only sparsely sampled, where no data were sampled, no data are generated for the modulating functions. When the full set of sparsely represented modulation functions are generated, there exists a one-to-one relationship between the original sampled data and the modulation function data. In the prior art of MACH, the sparsely sampled data are interpolated to generate missing data. In SLICK, the interpolation process is applied over the modulating function data. In this manner, the missing data for the modulating functions are estimated and filled in. After completing the interpolation across the spatial followed by temporal directions (or in reverse order, depending on the design of the sampling strategy) a full set of modulation functions are available. These are used to multiply the corresponding initial estimate data to generate the k-space representation. The resulting k-space data are then suitable for direct processing into images, e.g. by performing Fourier transformations.

SLICK Sampling and Data Conditioning Method for Weakly Correlated Slices

In some circumstances, the degree of correlation between slices will be relatively weak, thereby limiting the effectiveness of the SLICK method to acquire data faster. Under these circumstances, an alternative formulation of the SLICK acquisition, data conditioning, and processing into an image series is effective in restoring efficiency to the SLICK approach.

Sampling Pattern Generation

Consider generating either a full or a sparse sampling pattern (such as MACH) along the time direction, with the same temporal pattern considered for each slice. Secondly, generate a sparse sampling pattern along the slice direction, such as considering the acquisition of data from alternate slices. Thirdly, superimposed the spatial sampling pattern on the temporal pattern, such that for each k-space line position in any given slice, the original temporal pattern is either fully preserved or fully eliminated. In this way, if a particular k-space line is to be acquired for a particular slice, the original sparse (or full) sampling pattern along the temporal direction is preserved while for slices in which the slice sparse sampling pattern indicated that this line was to be omitted, it is fully omitted for those slices. Additionally, for all slices, extra sample points are added and dispersed over the time series such that at least one k-space line per k-space position is acquired over the time series. Data are sampled over the temporal and slice directions in a manner dictated by this combined sampling pattern.

Signal Conditioning

Data are conditioned by effectively transforming them into a Fourier domain. In this case, the temporally sampled data for each slice are subjected to interpolation along the time direction to generate data at the unsampled time points. The exception being that for k-space positions where only one k-space data line per time series was acquired, these data are not interpolated. For each slice, the time series of interpolated data are Fourier transformed along the time direction, generating the Fourier coefficients zero through the highest order coefficient available (e.g. if 16 time points were included then the highest order coefficient would be 7). The series of Fourier coefficient data thus generated form a pattern over the slice direction of data that are either present or absent at each k-space line position (directly corresponding to the sparse slice sampling pattern). To fill in the missing lines of coefficient data interpolation is performed along the slice direction. By this means, data for each Fourier coefficient are generated for each corresponding k-space line position for each slice. Depending on the sampling pattern applied, and the general form of the data, the first and higher order Fourier coefficients may be well represented, but typically, the zeroth order Fourier coefficient may not be well represented by interpolation along the slice direction. To approximate the zeroth order coefficient for each slice, the k-space lines that were only sampled once per series are substituted into the zeroth order coefficient (on a slice basis) such that the approximated zeroth order coefficient is composed of individual lines of k-space (sampled at one time point) or derived from the Fourier transform of the temporally interpolated data (above). This approximation of the zeroth order Fourier coefficient is used to replace the Zeroth coefficient data in the (slice interpolated) coefficient series above. These steps generate an approximation to the full set of Fourier coefficients. The estimate of k-space data for each slice, at each time point, is generated by performing an inverse Fourier transform along the inverse time direction of the Fourier coefficients (performed on a slice basis). These data are then suitable for generating into images by an in-plane 2D Fourier transform.

Use of SLICK for Accelerating the Acquisition

SLICK allows sparse sampling of data along the slice direction. In that SLICK allows generation of images from sparsely sampled data, it can be said to accelerate the acquisition. In discussing techniques that are designed to reduce the amount of data sampled in MRI 10 it is common to use the acceleration rate factor ‘R’ (e.g. an ‘R’ value of 4 corresponds to reducing the sampling density by a factor of 4, or equivalently accelerating the acquisition by a factor of 4).

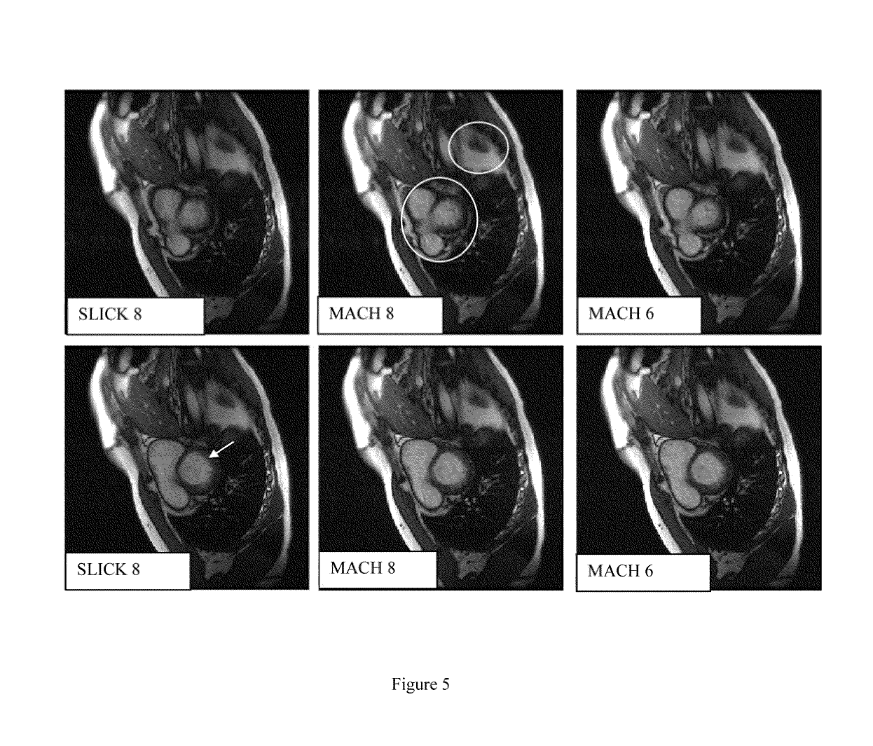

In simulations, SLICK was applied in conjunction with MACH to highly accelerate cardiac image data, FIG. 5. In this case, MACH was applied with an acceleration factor of 4 and SLICK was applied with an acceleration factor 2, to result in a net acceleration factor of 8. Compared with results of directly applying MACH at an acceleration of 8, the SLICK-MACH combination produced images with greater temporal fidelity and lower artifacts. To estimate how efficient SLICK was in producing additional acceleration, an image with a MACH acceleration of 6 was simulated, and shows comparable artifact and image features to the SLICK-MACH combination of 8, FIG. 5. Thus, the SLICK-MACH combination produced image quality similar to a MACH acceleration of 6, but achieving an acceleration of 8 without the addition of any scan overhead, making the contribution of SLICK about 33% more efficient than using MACH alone. FIG. 5 is a comparison of SLICK combined with MACH acceleration vs. MACH acceleration applied alone. Top row shows comparable end systolic images and lower row shows corresponding end diastolic images. The SLICK-MACH combined approach was applied with an acceleration factor of 8. The comparable MACH acceleration of 8 images shows more prominent striation artifacts in the heart and body regions (circled), while the MACH acceleration factor 6 images show comparable levels of artifact to the SLICK-MACH acceleration factor of 8 images and comparable sharpness in representation of cardiac walls (arrowed).

The SLICK approach is suitable for accelerating acquisitions where multiple slices are typically acquired, including cardiac cine imaging in the short axis orientation, or imaging multiple cardiac slices during passage of a contrast agent as used to assess myocardial perfusion. In the example of cardiac perfusion imaging, typically, high acceleration values are needed (e.g. 12-16) and typically at these high values, inclusion of multiple sources of acceleration are not generally feasible due to scan overhead adding more time than is saved by introducing multiple approaches. Since SLICK does not require additional overhead, say compared to MACH, it can be efficiently incorporated, thus making it ideal for highly accelerated scan applications. A particular advantage of SLICK applied to perfusion imaging, is that the high acceleration is achieved without requiring wider dispersion of data over the time direction. This is an advantage, since it may make such imaging schemes less sensitive to other sources of motion, such as respiratory motion.

Spatial Dimension Considerations

In SLICK, data are sparsely sampled over the spatial dimensions in a manner ensuring that each slice is temporally synchronized. Thus, the approach requires simultaneous temporal and spatial continuity of data. Two examples of applying SLICK are given to illustrate this aspect.

Multiple Slice Cardiac Functional Imaging

In cardiovascular MRI 10, it is common to acquire time resolved images over the cardiac cycle for a number of slices, say in the short axis view. Each slice is acquired separately from the others. To span a typical heart requires 12-15 such slices. At each slice location there may be 20 cardiac frames acquired, spanning the cardiac cycle from the start of the cycle to the end, spaced at equal time intervals. The slices are typically parallel to each other, such that there is no overlap between spatial locations of successive slices. In SLICK, the data for each slice are acquired in a temporally resolved manner, and sparse sampling is applied. After completion of the acquisition of the series of slices, the data sets are arranged in the computer such that the sparse sampling pattern of SLICK is apparent over the slice direction. The SLICK processing is applied to estimate the missing k-space data. It is envisaged that SLICK will typically be applied in conjunction with sparse sampling applied along the temporal direction. This temporal axis of the data requires additional processing, independent of the^{.} operation of SLICK.

Multiple Slice Cardiac Perfusion Imaging

In cardiac perfusion imaging, several slices of the heart are imaged as the contrast agent passes through the heart chambers and perfuses through the cardiac tissue. In this case, typically, for each slice imaged, only one frame per cardiac cycle is acquired. Thus, in the case of imaging multiple slices (e.g. in a parallel manner, as for cardiac functional imaging) the data set consists of several parallel slices, temporally synchronized with respect to individual heart beats (as opposed to temporal position within the heart cycle). To process the SLICK data, and generate the missing data dispersed along the spatial axis, the data set is arranged in the computer memory 16 after completion of the entire series of slices at multiple time points, and the SLICK processing applied.

Example of multiple Slice Cardiac Cycle Imaging

In time resolved cardiovascular imaging, the prior art approach of MACH has been used to accelerate the acquisition by performing sparse sampling along the time direction. When applied to cardiovascular imaging, it is common to acquire a set of slices, each time resolved. In the MACH approach, the accelerated acquisition was applied to each slice independently, and thus whether one slice or 20 slices were acquired, a similar approach was applied to each slice independently, with processing confined to the data from each slice. In SLICK, the opportunity to gain further acceleration is realized by considering the relationship between slices. In this example, consider acquiring 20 slices, each slice adjacent to the other with no overlap, and in a parallel orientation. In this example, the MACH and SLICK approaches are to be used to accelerate the scan by a factor of 8. The acceleration factor is to be derived from a MACH (temporal) acceleration factor of 4 and a SLICK (slice) acceleration factor of 2. Prior to the scan, the MACH sampling pattern suitable for an acceleration factor of 4 is generated. Secondly, the SLICK sparse sampling pattern is generated undependably of the MACH pattern, in this case a pattern based on acquiring every alternate line between slices is generated (the pattern is systematically permutated along the time axis to avoid temporally adjacent regions of unsampled data with regard to the SLICK pattern). The SLICK sparse sampling pattern is superimposed on the MACH pattern, such that the original MACH sampling pattern is reduced in density for any given frame a factor of 2. Thus, prior to initiation of the scan, the combined MACH and SLICK sampling patterns are generated and a sampling scheme is devised that reduces the sampling burden by a factor of 8 for each frame of a data. It is common to acquire cardiovascular data using segmentation, whereby a series of temporally adjacent k-space lines are assigned to one frame. In this example consider the number of views per segment (VPS) to be 16. For a matrix resolution of 256 lines of k-space, the calculated time in heart beats (HBs) per slice is given by the formula:

256/(MACH acceleration×SLICK acceleration×VPS)

In this example, the scan time per slice is reduced to 2 HBs. Assuming that the patient being imaged can hold their breath for 20 HBs, the acquisition of data for 20 slices can be acquired in two breath hold periods. During each breath hold, the k-space data for the combined slice-time data set are acquired and accumulated in the computer memory 16. After completion of the acquisition, the k-space data are interpolated in the manner of SLICK to estimate the missing k-space data values.

The key features of the SLICK scheme are:

1. Multiple strategies exist to sparsely sample a time resolved data set consisting of a 2D slice or a 3D volume. SLICK differs from these in that it is applicable to multiple 2D data sets.

2.SLICK can be applied with other sparse sampling schemes such as MACH without additional overhead. Thus, the combination of MACH and SLICK can achieve high levels of scan acceleration.

MACH describes an approach to acquire dynamic MRI 10 data rapidly. MACH involves utilizing a special sampling pattern to sparsely sample the MRI 10 signal space, termed k-space, over time. Associated with this specialized sampling pattern is a signal processing routing to interpolate the data and thereby fill in the unsampled points of k-space. The technique is capable of obtaining higher acceleration factors than comparable and competing approaches, attaining for any given acceleration factor improved fidelity of data and lower artifact levels. MACH means Multiple Acceleration Cycle Hierarchy.

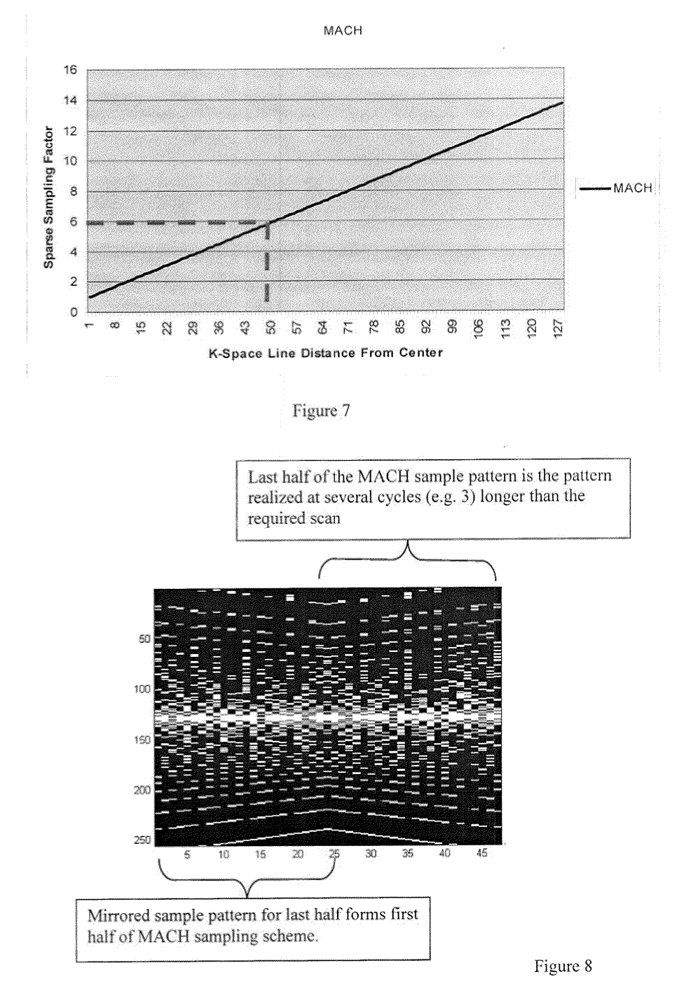

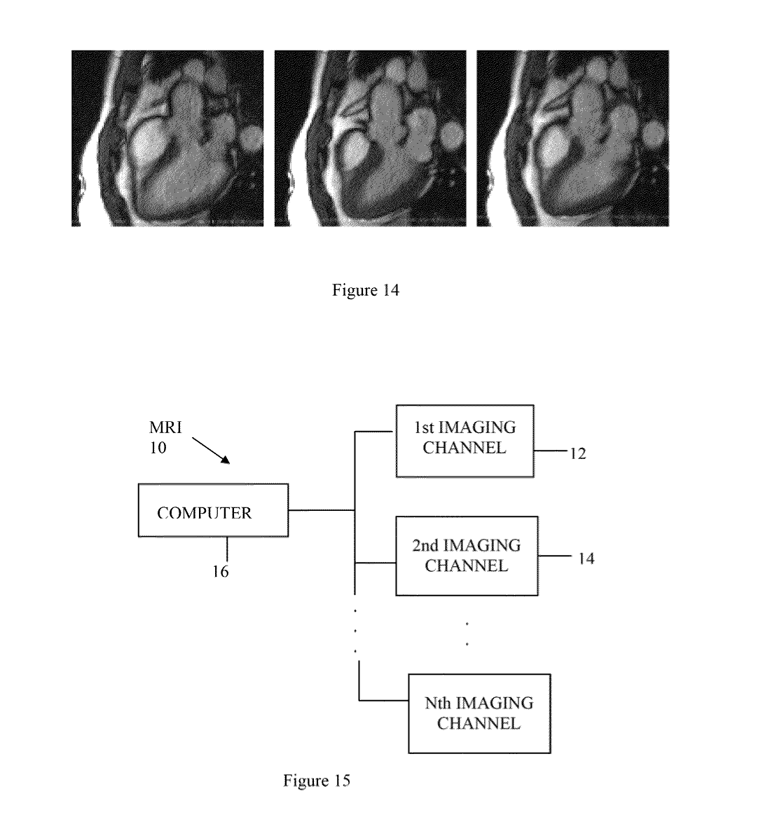

In MACH, the sparse sampling factor varies in small increments from the center of k-space to the periphery; e.g. at the center of k-space data are sampled at every time point, at the next line, data are sampled using a sparse factor of 1.1, the next line uses a sparse factor of 1.2, etc., until the outermost line of k-space employs a sparse factor of 3.2. Based on this simple premise, several refinements were developed to produce the MACH sampling pattern shown in FIG. 7. Simulations performed using conventional cine data to compare BRISK and MACH performance are shown in FIG. 13. FIG. 13 shows corresponding frames from three series: original (top), simulated BRISK (middle), and simulated MACH (lower) images. The original series utilized 256 lines of k-space while the BRISK and MACH series used 32 lines, corresponding to an acceleration factor of 8. Notice the clarity of myocardial walls and valve features in the MACH images seen against the blood pool signal, which has overall lower artifact content compared to the BRISK images. Note in particular the low degree of Gibbs ringing artifact in the first and last frames in the MACH series compared to the corresponding BRISK images. Also, note the fidelity with which cardiac features are followed compared to the original series. In this example, an acceleration factor of 8 was applied for BRISK and MACH. FIG. 14 shows MACH images simulated using an acceleration factor of 12, i.e. only 22 k-space lines out of a total of 256 were acquired at each cardiac phase. The MACH images follow the cardiac dynamics of the original series (FIG. 13) with remarkable fidelity. FIG. 14 shows simulated MACH images obtained with an acceleration factor of 12, corresponding to acquisition of 22 lines of k-space. Frames correspond to those of FIG. 13.

The MACH sampling and interpolation approach is suited for obtaining time resolved MRI 10 data in short scan times, such as imaging of the cardiovascular system are time resolved MR angiography, functional brain imaging, and real time MRI 10 applications, including interactive MRI 10, and MRI 10 guidance of surgical and interventional procedures.

The key features of the MACH scheme are:
1. Its use of variable sparse sampling strategy as opposed to a uniform sparse sampling strategy.
2. The sparse sampling factor increases in a smooth manner from the center of k-space to the periphery. This results in a highly irregular appearance to the sparse sampling pattern, whereas most approaches (including BRISK and KT-BLAST) use highly regular and structured sampling.
3. Approaches that use irregular sampling patterns have tended to use random or pseudo random approaches, whereas the MACH approach is based on a progression of rates.
4. MACH does not need any training data, and the technique is self-contained, with the reconstruction process being applied uniformly irrespective of the dynamic structure being observed.
5. Since MACH images are generated from a full set of k-space data, the signal to noise ratio is inherently high. This allows the MACH approach to be combined with other rapid imaging strategies to produce images in a faster mode. This is particularly important for real-time monitoring of interventions that can be applied in the MRI 10 scanner. Currently real-time imaging approaches in MRI 10 suffer from low temporal and spatial resolution. The MACH approach would allow higher resolution images to be acquired with a rapid update rate.

MACH acquires time resolved magnetic resonance imaging data in a sparse manner such that the sparse-sampling factor varies in a progressively increasing manner from the center of k-space. The sparsely sampled data are interpolated along the temporal dimension to populate data points that were not directly acquired.

The key features are 1) that the sparse sampling factor increases with distance from the center of k-space, and 2) that the sparse sampling factor varies in a smoothly continuous manner.

The sparse sampling pattern can be achieved by a number of algorithms that achieve the two key features of 1) applying an increasing sparse factor from the center of k-space outwards and 2) increasing the sparse factor in a smoothly progressive manner. An illustrative example is provided here for k-space data comprised of a square matrix of size 256×256 to be acquired in a symmetric manner at regular time intervals. In this example the sparse sampling factor is set at 1 for the center of k-space and it is incremented in steps of 0.1 for successive line positions towards the upper and lower boundaries of k-space. In this concrete example, the sampling pattern is as follows:
The two central lines of k-space are sampled at each of the pre-determined time intervals, i.e. sparse sampling factor of 1.
The two lines contiguous with the central lines are sampled at a sampling rate of 1:1.1 frames per time interval, i.e. sparse sampling factor 1.1.
The next two outermost lines of k-space are sampled at a rate of 1:1.2 frames per time interval, i.e. sparse sampling factor 1.2.
The pattern is continued until the outermost lines of k-space are sampled at rate of 1:13.7 frames per time interval, i.e. sparse sampling factor 13.7.

For the above example, a graph showing the smoothly incrementing sparse sampling factor is illustrated in FIG. 7, which is a linearly increasing function. FIG. 7 is a graph of example sparse sample factor for MACH. The vertical axis shows the sparse sampling factor to be applied at each line position. The horizontal axis shows the distance of the k-space line from the center of k-space. The dashed lines show how to interpret the plot: for k-space lines at ±50 from the center of k-space the sparse sampling factor to be applied is 6. Other functions that increase in a smooth manner include square and cubic relationships. To be smoothly varying the function should have a first order derivative that does not have any discontinuities, e.g. for the linear example of FIG. 7, the first order derivative (slope) is the same for all points considered, and in this case the second order derivative (rate of change of slope) is zero. In the case of a function involving a square term, the slope will smoothly increase while the rate of change of slope will be constant.

The formula used to determine the number of sampled points (NSP) sampled for an acquisition with a basic sample rate of R frames per second and a given sparse sampling factor (SSF) is given by the formula:

NSP=Floor(R/SSF)

Where the Floor operation selects the lowest whole number. For example, for R=100 frames per second and SSF=1.3, the number of sampled points is Floor(100/1.3)=76. As can be appreciated from this example, the time positions at which k-space data are sampled are in general irregularly spaced. The formula used to determine which points are sampled relative to some starting position is:

Sample Point=Floor(SPN*SSF)

Where the Floor operation selects the lowest whole number, and SPN is the sample point number.

For example, for SSF=1.3, the number of sampled points is 76. In this case SPN ranges from 1 to 76, and the relative time points at which data are sampled are 1, 2, 3, 5, 6, 7, 8, . . . 98, yielding a total of 76 points.

When using the above formulas to determine the sampled points relative to time position 1, a sampling pattern is generated that tends to be more heavily populated with points towards the beginning of the time series. To avoid this high concentration of sample points, the series is projected forward in time over several cycles and the sampling pattern for one later cycle is used as the basis for the sampling pattern. This generally results in a more even distribution of the sampled points. A number of algorithms can be used to accomplish this. The algorithm outlined here was used to produce the example images shown later:
Calculate the sample points by projecting the MACH sampling scheme over several cycles. For example when 3 cycles are chosen, if 100 time frames are to be acquired per cycle, then calculate the sampling scheme for time points ranging from 301 to 400.
Select the MACH sampling pattern for the last half of the cycle calculated above (e.g. time points 351 to 400).
Generate the mirror image of the half sampling pattern to define the first half of the sample pattern (e.g. sample points are to be based on the pattern of time points 400-351 followed by 351-400), such that where the two halves meet, the sample pattern is identical, as indicated in FIG. 8.

FIG. 8 is a schematic of the k-space-temporal sampling pattern of the MACH sparse sampling scheme. The vertical axis represents the lines of k-space to be acquired, and the horizontal axis represents the time axis. For a scan planned to obtain a number sampled time points, SP, the sample pattern of the last half of the scheme was generated by calculating the sample pattern for a time series at a multiple of SP time points (e.g. 3×SP). The latter half of this sampling pattern is mirrored and applied to the first half of the sample pattern. The pattern can be applied to sample SP sample points.

The sampling scheme outlined in FIG. 8 still typically results in a slightly higher concentration of sample points at certain irregularly distributed time points. This becomes a limiting factor when using the sampling scheme to reduce the scan time. To avoid this, some slight adjustment of the sample points can be made to distribute them more evenly. There are several algorithms that can accomplish this. A representative algorithm is:
Redistribute sample points from time positions that have more than the average number of points to the same k-space position at the nearest time point that has fewer than the average number of sampled points.

The MACH sampling pattern is used to guide the acquisition of the phase-encoded lines of k-space for a time resolved acquisition. The MACH sampling pattern can be applied directly to any MRI 10 acquisition approach that acquires k-space as a series of parallel lines. The sparsely sampled time resolved k-space data are stored in arrays in the computer 16. A record is kept to identify the order in which data were acquired.

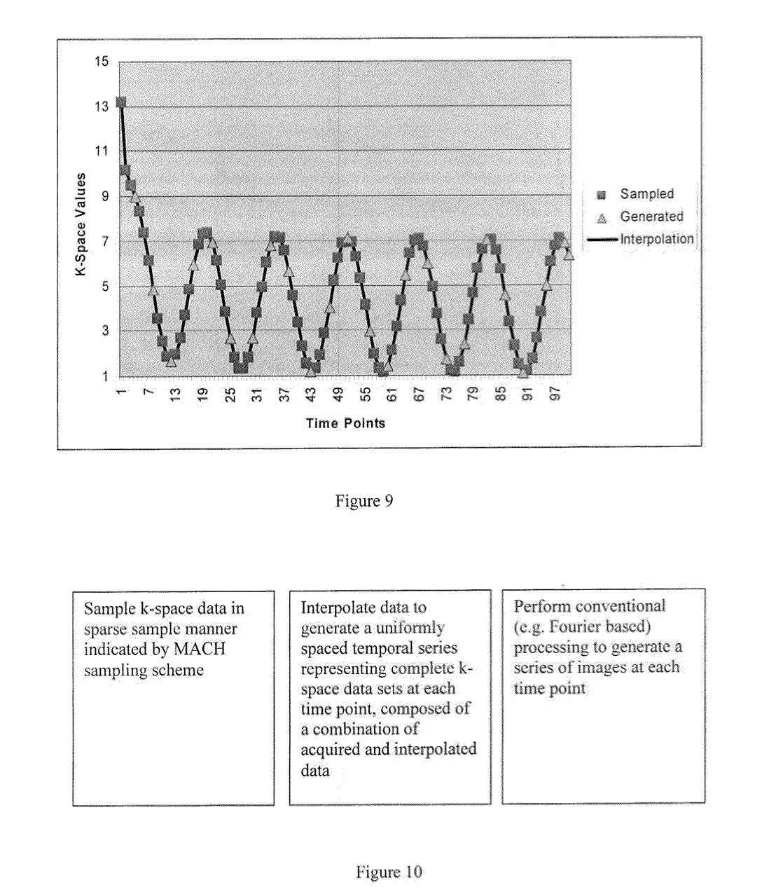

For a given k-space line position, the records of the MACH sampling pattern are used to extract corresponding k-space lines for each time point. For each point of each k-space line, the time series of points are subjected to an interpolation procedure to generate k-space data corresponding to points that were not sampled, as indicated in FIG. 9. FIG. 9 shows the interpolation scheme is illustrated. Red squares represent sampled data obtained at discrete time points. The continuous blue line represents the interpolated function fitted to the sampled points. The green triangles are the interpolated points represented at discrete time points such that the combination of original (squares) and interpolated (triangles) discrete points describe a uniformly spaced series corresponding to the fully sampled series. Several algorithms can be used to interpolate the sparsely sampled data. A representative algorithm is:
For a given k-space line, the sampled data are extracted and the time points at which they were acquired are noted.
In the case of data that are expected to be cyclic, such as cardiac motion, the sampled period over which the data are captured is duplicated and positioned prior to the sampled points and following the sampled points. The corresponding time points are accordingly projected backwards or forwards in time respectively, and this information is stored.
In the case that data are not expected to be cyclic for following treatment can be performed: if data for the first time point are not sampled, data from the first sampled point are duplicated backwards to populate each time point all the way back to the first time point; similarly, if data for the last time point are not sampled, data from the last sampled point are duplicated forward to populate each time point all the way to the last time point.
For the extended multiple cycle data or the single cycle data amended as above, data interpolation is performed: either between the extended time points over three cycles (for periodic data) or between the first and last time points of the single cycle (for non-periodic data). Interpolation can be performed by a number of means including spline or cubic interpolation.
A combination of interpolated and acquired data are extracted for time points ranging from the first point to the last point, such that data for each intermediate time point are prepresented.

A block diagram showing the key steps in implementing MACH are shown in FIG. 10.

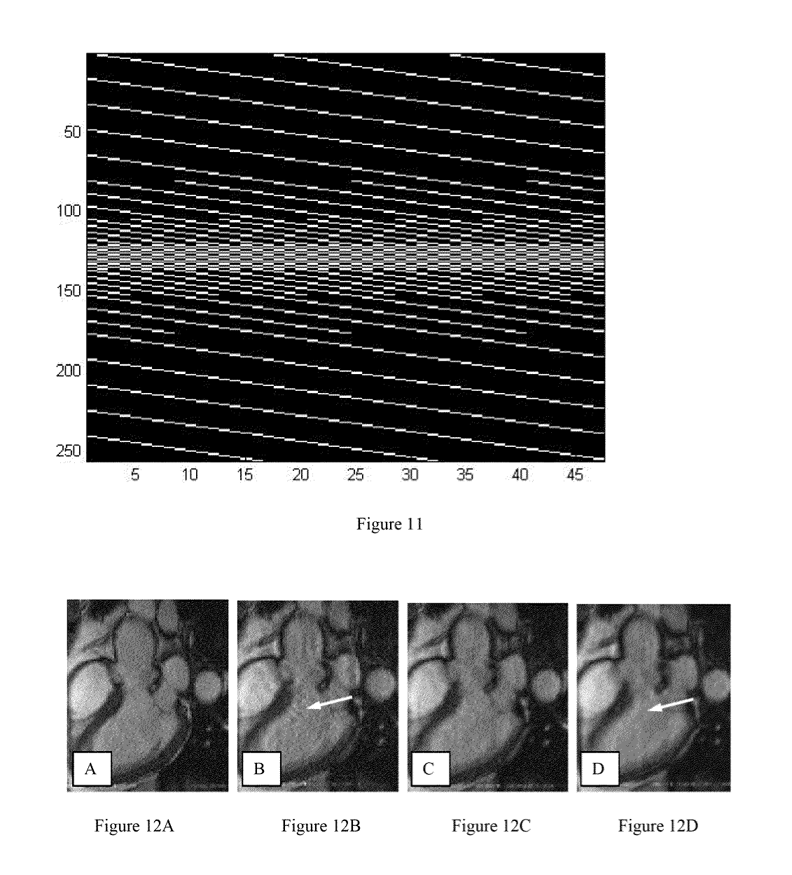

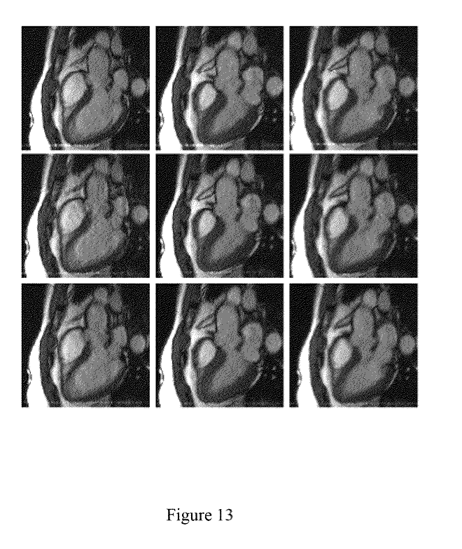

Previously, a related rapid imaging approach termed BRISK was described. The present invention and BRISK are similar, but there are important differences. In the previously described BRISK approach, the sampling of k-space data over the time is performed in a sparse manner (i.e. data sampling is distributed over the so called k-t domain, i.e. k-space-time domain). A key feature of BRISK is that several sparse sampling factors are employed, with the lowest factor applied towards the center of k-space and higher factors applied towards the periphery of k-space, FIG. 11. FIG. 11 is a schematic of the k-space-temporal sampling patterns of the BRISK sparse sampling scheme. The vertical axis represents the k-space axis with 256 lines. The horizontal axis represents the cardiac cycle at 48 distinct, uniformly spaced time points. The sample pattern represents an acceleration factor of 8, whereby only 32 lines are sampled at any given cardiac phase. In BRISK, the sparse sampling factors were applied to contiguous blocks of k-space, whereas in MACH, each sparse sampling factor is applied separately to each line of k-space. In BRISK, the sparse sampling factors were generally related to each other by multiples of 2, and each sparse sampling factor was applied to a block of k-space lines, whereas in MACH the sparse sampling factor increases in a smoothly varying manner and is applied to one line position. In BRISK, the sparse sampling factors that were applied to blocks of k-space that were dynamically sampled incremented by large factors, e.g. 2, allowing exact interleaving of the sampling patterns (e.g. the regions sampled at a sparse factor of 4 fit in the spaces left by regions sampled at a sparse factor of 2, etc), whereas in MACH the sparse sampling factor increases in such a manner that the sampling pattern between adjacent lines do not in general fall in a regular interleaved pattern. The key advantage of the smoothly varying sampling pattern of MACH compared to BRISK is that Gibbs ringing artifacts are reduced by approximately 50%. In the example of FIGS. 12a-12d, simulated MACH images obtained with a time reduction factor of 12 produce comparable Gibbs artifacts to a BRISK scan obtained with a time reduction factor of 8. FIGS. 12a-12d show corresponding frames illustrate the relative performance of BRISK and MACH with respect to Gibbs ringing artifact. A) Original image obtained using 256 k-space lines, B) BRISK image obtained by sampling a total of 32 lines, representing time reduction factor of 8, with noticeable Gibbs ringing artifacts, arrow points to representative artifact and others are present, C) MACH image obtained with a total of 32 lines sampled, representing a reduction factor of 8, without prominent Gibbs artifacts, D) MACH image with a total of 22 lines sampled, representing a reduction factor of 12, with Gibbs artifacts comparable to those seen in (B) corresponding to BRISK with a reduction factor of 8.

Since BRISK was introduced, others have introduced k-t sampling approaches, such as KT-BLAST, and SLAM. In general, these approaches employ a single sparse sampling factor that is uniformly applied for all k-space lines. Since a uniform sparse sampling factor is applied, there are no sudden transitions between k-space regions and thus Gibbs ringing is not a dominant artifact in these images. These techniques work best when the dynamic imaging region is restricted to 1/n of the field of view, where n is the sparse sampling factor. Under conditions where the dynamic region exceeds this extent, this class of approach is dominated by temporal blurring of each time frame. The techniques are estimated to perform at a level 50% less efficiently than BRISK, making them 100% less efficient than MACH.

Although the invention has been described in detail in the foregoing embodiments for the purpose of illustration, it is to be understood that such detail is solely for that purpose and that variations can be made therein by those skilled in the art without departing from the spirit and scope of the invention except as it may be described by the following claims.

1. A method of using an MRI for a patient comprising the steps of:
sparsely sampling multiple slices of k-space data across a spatial dimension and a temporal dimension with imaging coils to produce associated signals;
receiving with a receiving coil the associated signals of the multiple slices;
storing the associated signals of the multiple slices in a memory; and
processing with a processing unit the associated signals of the multiple slices altogether at essentially a same time to produce an image of the patient.

2. The method as described in claim 1 wherein the sampling step includes the step of sampling multiple slices over the spatial dimension, with each slice temporally synchronized.

3. The method as described in claim 2 including the step of applying a sparse sampling pattern along a slice direction.

4. The method as described in claim 3 including the step of conditioning the signals along the slice direction.

5. The method as described in claim 4 including the step of performing signal estimation of missing data by interpolation between corresponding points along the slice direction.

6. The method as described in claim 5 wherein the conditioning step includes the step of using time data for each slice to interpolate along a time direction thereby filling in all time points either with the data or with a temporally interpolated value.

7. The method as described in claim 6 including the step of conditioning the k-space data by subtracting an estimate of the k-space data from the sampled data.

8. The method as described in claim 7 including the step of interpolating between the conditioned k-space data with respect to the slice direction to estimate each missing k-space data.

9. The method as described in claim 8 including the step of adding in the k-space data estimates to the spatially interpolated data to produce full k-space data sets for each timeframe for each slice.

10. A method as described in claim 9 including the step of performing a second interpolation along the time direction of original sampled data and spatially interpolated data.

11. An MRI for a patient comprising:
imaging coils for sparsely sampling multiple slices of k-space data across a spatial dimension and a temporal dimension to produce associated signals;
a receiving coil which receives the associated signals of the multiple slices;
a memory in which the associated signals of the multiple slices are stored; and
a processing unit which processes the associated signals of the multiple slices altogether at essentially a same time to produce an image of the patient.

12. The MRI as described in claim 11 wherein the image coil samples multiple slices over the spatial dimension, with each slice temporally synchronized.

13. The MRI as described in claim 12 wherein the image coil applies a sparse sampling pattern along a slice direction.

14. The MRI as described in claim 13 wherein the processing unit conditions the signals along the slice direction.

15. The MRI as described in claim 14 wherein the processing unit performs signal estimation of missing data by interpolation between corresponding points along the slice direction.

16. The MRI as described in claim 15 wherein the processing unit uses time data for each slice to interpolate along a time direction thereby filling in all time points either with the data or with a temporally interpolated value.

17. The MRI as described in claim 16 wherein the processing unit conditions the k-space data by subtracting an estimate of the k-space data from the sampled data.

18. The MRI as described in claim 17 wherein the processing unit interpolates between the conditioned k-space data with respect to the slice direction to estimate each missing k-space data.

19. The MRI as described in claim 18 wherein the processing unit adds in the k-space data estimates to the spatially interpolated data to produce full k-space data sets for each timeframe for each slice.

20. A MRI as described in claim 19 wherein the processing unit performs a second interpolation along the time direction of original sampled data and spatially interpolated data.

21. A method of using an MRI for a patient's heart comprising the steps of:
sparsely sampling multiple slices of k-space data of the heart across a spatial dimension and a temporal dimension with imaging coils to produce associated signals;
receiving with a receiving coil the associated signals of the multiple slices;
storing the associated signals of the multiple slices in a memory; and
processing with a processing unit the associated signals of the multiple slices altogether at essentially a same time to produce an image of the patient.
